(19) United States
(12) Patent Application Publication
(10) Pub. No.: US 2026/0331419 A1
(43) Pub. Date: Oct. 22, 2026

(54) CHARGED PARTICLE MULTI-BEAM WRITING METHOD, CHARGED PARTICLE MULTI-BEAM WRITING APPARATUS, AND COMPUTER-READABLE RECORDING MEDIUM

(71) Applicant: NuFlare Technology, Inc., Yokohama-shi (JP)

(72) Inventors: Tomoo MOTOSUGI, Yokohama-shi (JP); Toshihiro SAGA, Yokohama-shi (JP)

(73) Assignee: NuFlare Technology, Inc., Yokohama-shi (JP)

(21) Appl. No.: 19/546,665

(22) Filed: Feb. 23, 2026

(30) Foreign Application Priority Data
Apr. 17, 2025 (JP) 2025-068320

(51) Int. Cl. H01J 37/302; H01J 37/04; H01J 37/20; H01J 37/317; H10P 34/00

(52) U.S. Cl. CPC H01J 37/3026; H01J 37/045; H01J 37/20; H01J 37/3177; H10P 34/10; H01J 2237/202; H01J 2237/30472; H01J 2237/31766

(57) ABSTRACT

In one embodiment, a charged particle multi-beam writing method includes calculating, from writing data, an irradiation time for each beam of each shot of a multi-beam of charged particles, generating irradiation time control data corresponding to the calculated irradiation time for each beam at an irradiation dose control resolution determined for each region of a plurality of regions into which a writing area of a substrate is virtually divided, and performing shots of the multi-beam based on the irradiation time control data.

### CROSS REFERENCE TO RELATED APPLICATION

This application is based upon and claims benefit of priority from the Japanese Patent Application No. 2025-68320, filed on Apr. 17, 2025, the entire contents of which are incorporated herein by reference.

### FIELD

The present invention relates to a charged particle multi-beam writing method, a charged particle multi-beam writing apparatus, and a computer-readable recording medium.

### BACKGROUND

With the increasing integration density of LSIs, the circuit linewidths used in semiconductor devices have been progressively reduced. To form a desired circuit pattern on a semiconductor device, a reduction projection exposure apparatus is used to transfer a high-precision original pattern formed on a light-shielding film or the like on a glass substrate (referred to as a mask, or, when used in a stepper or scanner, a reticle) onto a wafer. Electron beam lithography is used to form such high-precision original patterns, in which a resist pattern is created using an electron beam writing apparatus.

In a multi-beam writing apparatus using a blanking aperture array substrate, for example, a multi-beam including a plurality of individual beams is formed by passing an electron beam emitted from an electron source through a shaping aperture array substrate with multiple apertures. Downstream of the shaping aperture array substrate, the blanking aperture array substrate is provided. The blanking aperture array substrate includes, for each individual beam of the multi-beam, a pair of electrodes (blanker) for deflecting the beam and an aperture for beam passage formed between the pair of electrodes. These elements are arranged in an array.

The blanking aperture array substrate switches the blanking deflection of each individual beam of the multi-beam between off and on by controlling the pair of electrodes corresponding to each beam to the same or different potentials. A beam deflected by the blanker is blocked, whereas a beam that is not deflected is incident on the substrate.

In the blanking aperture array substrate, an individual blanking mechanism for driving each blanker is provided, and irradiation time control data is transferred to each mechanism. Increasing the number of bits of the irradiation time control data and shortening the irradiation time corresponding to the least significant bit improves the irradiation dose control resolution, thereby enhancing pattern writing accuracy. However, a larger number of bits increases the size of the irradiation time control data, leading to longer data transfer times and, consequently, a longer writing time.

When multiple writing passes are performed, a technique was disclosed in which the number of bits of irradiation time control data is fixed based on the maximum irradiation dose for each pass, and a pattern is written on the substrate with a constant irradiation dose control resolution (see, for example, Japanese Patent Laid-Open Publication No. 2016-184671). However, the pattern written on the substrate includes figures of various sizes and shapes, and the required writing accuracy varies for each figure. If all figures are written with a high irradiation dose control resolution, the writing process time is increased. On the other hand, if all figures are written with a low irradiation dose control resolution, the writing process time is reduced, but some patterns may not meet dimensional accuracy requirements.

### BRIEF DESCRIPTION OF THE DRAWINGS

FIG. 1 is a schematic diagram of a charged particle multi-beam writing apparatus according to an embodiment of the present invention.

FIG. 2 is a plan view of a shaping aperture array substrate. FIG. 3 is a cross-sectional view illustrating the configuration of a blanking aperture array substrate.

FIG. 4 is a diagram illustrating an example of a writing operation.

FIG. 5 is a schematic configuration diagram of a control circuit in the blanking aperture array substrate.

FIG. 6 is a configuration diagram of an input/output circuit and a cell array circuit.

FIG. 7 is a schematic configuration diagram of an individual blanking mechanism.

FIG. 8 is a diagram illustrating an example of irradiation steps within one shot cycle.

FIG. 9 is a diagram illustrating an example of beam-on timing.

FIG. 10 is a diagram illustrating an example of irradiation steps within one shot cycle.

FIG. 11 is a diagram illustrating an example of accuracy information assigned to each figure.

FIG. 12 is a diagram illustrating a table associating dimensional accuracy with irradiation dose control resolution.

FIG. 13 is a flowchart for explaining the writing method according to the embodiment.

FIG. 14 is a diagram illustrating a table associating the area ratio of figures having a pattern density equal to or greater than a predetermined value with irradiation dose control resolution.

### DETAILED DESCRIPTION

In one embodiment, a charged particle multi-beam writing method includes calculating, from writing data, an irradiation time for each beam of each shot of a multi-beam of charged particles, generating irradiation time control data corresponding to the calculated irradiation time for each beam at an irradiation dose control resolution determined for each region of a plurality of regions into which a writing area of a substrate is virtually divided, and performing shots of the multi-beam based on the irradiation time control data.

Hereinafter, embodiments of the present invention will be described with reference to the drawings. In the embodiments, a configuration using an electron beam is described as an example of a charged particle beam. However, the charged particle beam is not limited to an electron beam and may be an ion beam.

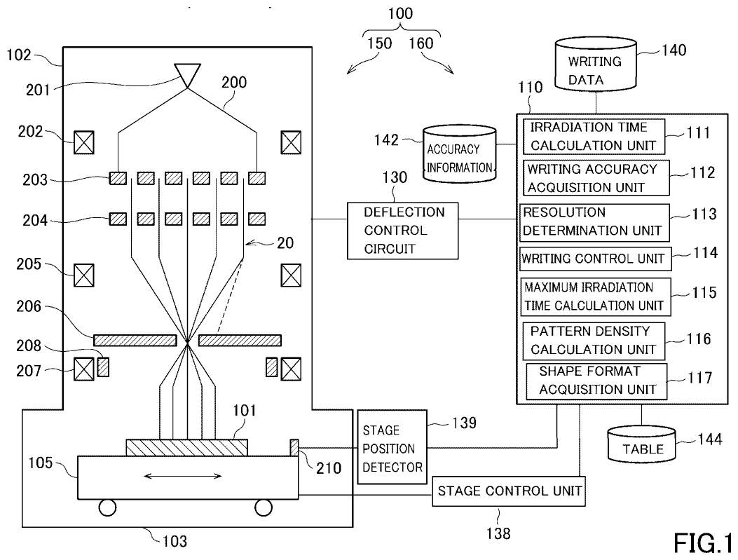

FIG. 1 is a schematic configuration diagram of a writing apparatus according to an embodiment. As shown in FIG. 1, the writing apparatus 100 includes a writing unit 150 and a control unit 160. The writing apparatus 100 is an example of a charged particle multi-beam writing apparatus. The writing unit 150 includes an electron optical column 102 and a writing chamber 103. Inside the electron optical column 102, an electron source 201, an illumination lens 202, a shaping aperture array substrate 203, a blanking aperture array substrate 204, a reduction lens 205, a limiting aperture member 206, an objective lens 207, and a deflector 208 are arranged.

Inside the writing chamber 103, an XY stage 105 is provided. A substrate 101 to be written is placed on the XY stage 105. A resist, which is exposed by the electron beam, is applied to the upper surface of the substrate 101. The substrate 101 is, for example, a mask blank or a semiconductor substrate (silicon wafer) used for manufacturing a semiconductor device. In addition, a mirror 210 for stage position measurement is provided on the XY stage 105.

The control unit 160 includes a control computer 110, a deflection control circuit 130, a stage control unit 138, a stage position detector 139, and storage units 140, 142, and 144. Writing data is input from the outside and stored in the storage unit 140. The writing data defines information for a plurality of figure patterns to be written. Specifically, for each figure pattern, the shape format, coordinates, size, and the like are defined.

The control computer 110 includes an irradiation time calculation unit 111, a writing accuracy acquisition unit 112, a resolution determination unit 113, and a writing control unit 114. In addition, the control computer 110 may include at least one of a maximum irradiation time calculation unit 115, a pattern density calculation unit 116, and a shape format acquisition unit 117. At least part of the control computer 110 may be configured from hardware, such as an electrical circuit, or may be configured from software. When configured with software, a program for implementing at least part of the functions of the control computer 110 may be stored on a recording medium, such as a CD-ROM, and loaded into a computer for execution.

The stage control unit 138 controls the movement speed of the XY stage 105. The stage position detector 139 irradiates the mirror 210 with a laser, receives the reflected light from the mirror 210, and detects the position of the XY stage 105 using a laser interferometry method.

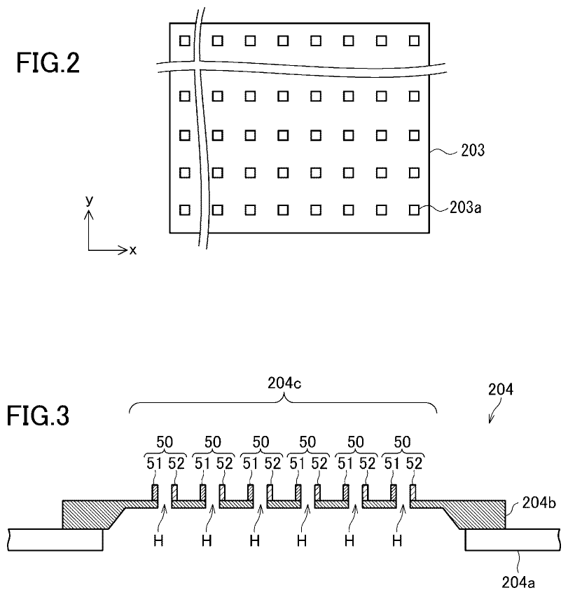

FIG. 2 is a conceptual diagram illustrating the configuration of the shaping aperture array substrate 203. The shaping aperture array substrate 203 is a plate-like member, and, as shown in FIG. 2, a plurality of apertures 203a are formed along the longitudinal (y) direction and the lateral (x) direction. Each aperture 203a is preferably formed as a rectangle having the same or substantially the same dimensions and shape. The shape of each aperture 203a may be circular.

The electron beam 200 emitted from the electron source 201 (emission unit) illuminates the shaping aperture array substrate 203 via the illumination lens 202. The electron beam 200 illuminates a region of the shaping aperture array substrate 203 that includes a plurality of apertures 203a. A portion of the electron beam 200 passes through the plurality of apertures 203a of the shaping aperture array substrate 203, while the remaining beam is blocked by the shaping aperture array substrate 203, thereby forming a multi-beam 20 including a plurality of individual beams.

As shown in FIG. 3, the blanking aperture array substrate 204 includes a support base 204a and a semiconductor substrate 204b made of silicon or the like provided on the support base 204a. The central portion of the semiconductor substrate 204b is thinned from the back side and processed into a membrane region 204c having a thin film thickness. The periphery surrounding the membrane region 204c forms a thick outer peripheral region, and the semiconductor substrate 204b is held on the support base 204a at the back side of the outer peripheral region. The central portion of the support base 204a has an opening, and the position of the membrane region 204c is located within the opened region of the support base 204a.

In the membrane region 204c, beam passage holes H are formed corresponding to the arrangement positions of the plurality of apertures 203a of the shaping aperture array substrate 203. Each passage hole H is provided with a blanker 50, which consists of a pair of electrodes 51 and 52. One individual beam of the multi-beam 20 passes through the passage hole H and between the pair of electrodes. The blanker 50 switches the deflection of the beam passing through the passage hole H on and off by keeping one electrode 52 grounded at a ground potential and switching the other electrode 51 between the ground potential and a potential other than the ground potential. In this manner, the blanker 50 performs blanking control to set each beam of the multi-beam to either a beam-on state or a beam-off state.

When controlling one individual beam of the multi-beam to a beam-on state, the opposing electrodes 51 and 52 of the blanker 50 are controlled to the same potential, and the blanker 50 does not deflect the individual beam passing through the passage hole H. When controlling the beam to a beam-off state, the opposing electrodes 51 and 52 of the blanker 50 are controlled to different potentials, and the blanker 50 deflects the individual beam passing through the passage hole H.

The multi-beam 20 that has passed through the blanking aperture array substrate 204 is reduced by the reduction lens 205 and then proceeds toward the central aperture formed in the limiting aperture member 206.

An individual beam controlled to the beam-off state is deflected by the blanker 50 and follows a trajectory outside the aperture of the limiting aperture member 206, and is thus blocked by the limiting aperture member 206. On the other hand, an individual beam controlled to the beam-on state is not deflected by the blanker 50 and passes through the aperture of the limiting aperture member 206.

The trajectory of the beam is adjusted by an alignment coil (not shown) so that a beam controlled to the beam-on state is positioned within the aperture of the limiting aperture member 206. In FIG. 1, the trajectory of the multi-beam is adjusted so that the beam-on multi-beam converges to a single point at the position of the limiting aperture member 206. It is preferable to adjust the alignment coil so that this single point is located at the center of the aperture of the limiting aperture member 206.

In this manner, the on/off operation of deflection by the blanker 50 in combination with the beam blocking by the limiting aperture controls the on/off state of each beam of the multi-beam. In other words, blanking control is performed.

As described above, the blanking aperture array substrate 204 individually performs blanking control of each beam of the multi-beam 20 using a plurality of blankers 50. In other words, the on/off state of each beam of the multi-beam 20 can be independently switched between beam-on and beam-off. In a pattern writing process onto the substrate 101, all beams of the multi-beam are initially controlled to the beam-off state, and only predetermined beams are controlled to the beam-on state by blanking control. After a predetermined time elapses, all beams are returned to the beam-off state. Through this blanking control, only selected beams of the multi-beam can be maintained in the beam-on state for a predetermined time.

The multi-beam that has passed through the limiting aperture member 206 is focused by the objective lens 207 and imaged on the substrate 101 as a pattern image with a desired reduction ratio. Ideally, the multi-beam is arranged on the substrate 101 with a pitch obtained by multiplying the array pitch of the plurality of apertures 203a of the shaping aperture array member 203 by the aforementioned desired reduction ratio. Each beam that has passed through the limiting aperture member 206 (i.e., all beams of the multi-beam that are in the beam-on state) is collectively deflected in the same direction by the deflector 208 and irradiated onto a desired position on the substrate 101 with focus maintained on the substrate surface.

Irradiation of the substrate 101 by the multi-beam is possible whether the XY stage 105 is stationary or continuously moving. When the XY stage 105 is continuously moving, the stage position detector 139 measures the change in stage position, and based on the result, the deflector 208 continuously adjusts the position of the multi-beam to follow the movement of the XY stage 105. This is referred to as stage-tracking deflection. By performing stage-tracking deflection, the position of the multi-beam on the substrate 101 can be fixed. At least while irradiating the substrate 101 with the beam, stage-tracking deflection is performed to control each beam of the multi-beam to remain stationary on the substrate 101.

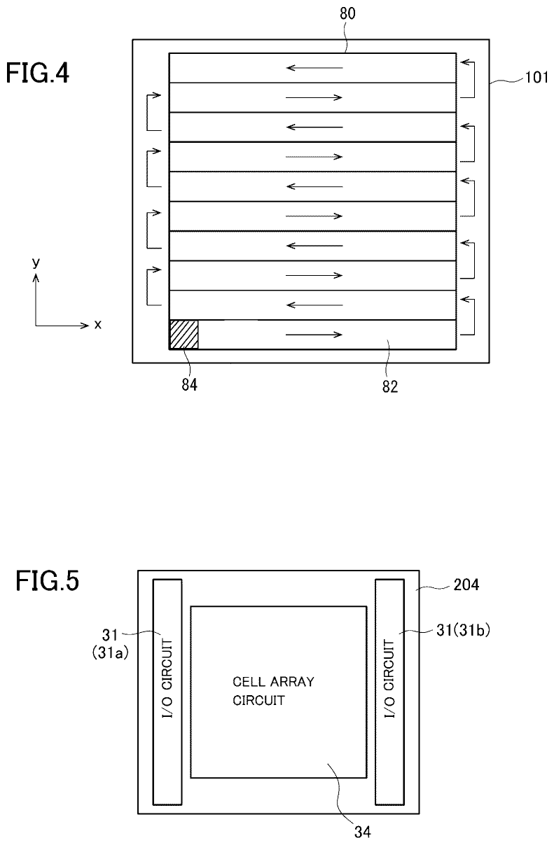

FIG. 4 is a diagram illustrating an example of a writing operation. As shown in FIG. 4, the writing region 80 of the substrate 101 is virtually divided into a plurality of stripe regions 82 extending, for example, in the y-direction (first direction) with a predetermined width. First, the XY stage 105 is moved so that an irradiation region 84, which can be irradiated by a single shot of the multi-beam, is positioned at the left end of the first stripe region 82, and the writing is started.

When writing the first stripe region 82, the XY stage 105 is moved in the −x direction so that writing progresses relatively in the +x direction. During writing, the pixels exposed by the multi-beam are switched by deflecting the multi-beam at least in the Y direction using the deflector. By repeatedly switching exposure pixels and performing exposure operations, the multi-beam exposes all pixels defined within the stripe region 82. The XY stage 105 is continuously moved at a predetermined speed. After completing the writing of the first stripe region 82, the stage position is moved in the-y direction to adjust the position so that the irradiation region 84 is at the right end of the second stripe region 82. Subsequently, the XY stage 105 is moved in the +x direction, and writing is performed in the −x direction.

In the third stripe region 82, writing is performed in the +x direction, and in the fourth stripe region 82, writing is performed in the −x direction. By alternating the writing direction for each stripe region 82, the writing time can be reduced. Alternatively, each stripe region 82 may be written in the same direction.

In addition to the blankers 50 and the passage holes H described above, the blanking aperture array substrate 204 includes a control circuit for applying a desired voltage to the blankers 50. As shown in FIG. 5, this control circuit includes an input/output circuit 31 and a cell array circuit 34.

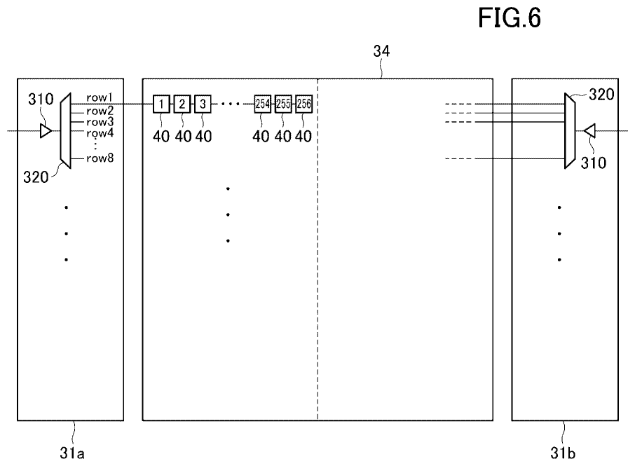

As shown in FIG. 6, the cell array circuit 34 includes a plurality of cells that constitute individual blanking mechanisms 40 for driving the blankers 50. FIG. 6 illustrates an example of a blanking aperture array substrate having a cell array circuit and blankers comprising 512 rows and 512 columns, totaling 262,144 cells. One individual blanking mechanism 40 drives one blanker 50. The input/output circuit 31 outputs data received from the deflection control circuit 130 to the cell array circuit 34. For example, the input/output circuit 31 includes an input/output circuit 31a that outputs data to individual blanking mechanisms 40 arranged on one half of the cell array circuit 34, and an input/output circuit 31b that outputs data to individual blanking mechanisms 40 arranged on the other half.

The input/output circuit 31 is provided with a plurality of selectors 320 (demultiplexers). Each selector 320 receives irradiation time control data defining the on/off state of each beam via an amplifier 310 and outputs the data through a corresponding output line. A plurality of individual blanking mechanisms 40 are connected in series to each output line.

Each selector 320 has, for example, eight output lines row 1 to row 8, with 256 individual blanking mechanisms 40 connected to each output line. By arranging 64 selectors 320 in each of the input/output circuits 31a and 31b, irradiation time control data can be transferred to all 512×512 individual blanking mechanisms 40 that constitute the cell array circuit 34.

As shown in FIG. 7, the individual blanking mechanism 40 includes a shift register 41, a pre-buffer 42, a buffer 43, a data register 44, a NAND circuit 45, and an amplifier 46. The shift register 41 transfers data output from the shift register of the preceding cell to the shift register of the subsequent cell in accordance with a clock signal (SHIFT).

The pre-buffer 42 stores the irradiation time control data for the corresponding cell, which is output from the shift register 41, in accordance with a clock signal (LOAD1).

The buffer 43 captures and holds the output value of the pre-buffer 42 in accordance with a clock signal (LOAD2).

The data register 44 captures and holds the output value of the buffer 43 in accordance with a clock signal (LOAD3).

The NAND circuit 45 receives the output signal of the data register 44 and a shot enable signal (SHOT_ENABLE). The output signal of the NAND circuit 45 is supplied to the electrode 51 of the blanker 50 via the amplifier 46 (driver amplifier). Each clock signal and the shot enable signal are provided from the control computer 110 via the deflection control circuit 130.

When both the output signal of the data register 44 and the shot enable signal are High, the output of the NAND circuit 45 becomes Low, causing the electrodes 51 and 52 to be at the same potential. As a result, the blanker 50 does not deflect the beam, and the beam is turned on. When at least one of the output signal of the data register 44 or the shot enable signal is Low, the output of the NAND circuit 45 becomes High, causing the electrodes 51 and 52 to be at different potentials. Consequently, the blanker 50 deflects the beam, and the beam is turned off.

The shot enable signal is input to the NAND circuits 45 of all individual blanking mechanisms 40. By setting the shot enable signal to Low, all beams can be turned off regardless of the output signal of the data register 44.

When the shot enable signal is maintained High, the on/off state of the beam is switched according to the output of the data register 44. That is, the beam is turned on when the irradiation time control data is 1 (High), and the beam is turned off when the irradiation time control data is 0 (Low).

In order to form a resist pattern with desired dimensions through exposure of the resist, it is necessary to control the irradiation dose to an appropriate value. That is, in blanking control, it is necessary not only to switch the beam on/off but also to control the duration for which the beam is on. Since the blanking control is performed by logic circuits, i.e., digital circuits, the irradiation time is represented by an integer value. For example, the irradiation time T is divided by a quantization unit Δ to calculate a quantized irradiation time N. The quantization unit Δ can be set to various values, such as 1 ns.

In multi-beam writing, some individual beams of the multi-beam are positioned inside a pattern, while other individual beams are positioned at the edges of the pattern or in regions without a pattern. Therefore, the irradiation time control data allocated to each beam of the multi-beam is not the same for all beams. Accordingly, the irradiation time of each beam in the multi-beam needs to be controlled independently.

As one form of such control, a single shot is divided into multiple irradiation steps of different lengths, and each beam is turned on only for the irradiation steps necessary to achieve the desired exposure time for that beam. For this purpose, the quantized value N is converted into an n-bit binary number, and the length of each irradiation step corresponding to each bit of the n-bit binary number—that is, the time during which the beam is turned on—is set to a decimal value corresponding to the binary bit multiplied by Δ.

For example, when the quantized irradiation time N=50 and the number of bits n=8, based on the relationship expressing the decimal number as a sum of powers of two, 50=2⁵+2⁴+2¹, the irradiation time control data is uniquely determined as “00110010.” Similarly, when the quantized irradiation time N=100 and n=8, the irradiation time control data becomes “01100100.”

The least significant bit of the irradiation time control data corresponds to the irradiation step of duration 1Δ. The second least significant bit corresponds to the irradiation step of duration 2Δ. The third least significant bit corresponds to the irradiation step of duration 4Δ. The fourth least significant bit corresponds to the irradiation step of duration 8Δ. The fifth least significant bit corresponds to the irradiation step of duration 16Δ. The sixth least significant bit corresponds to the irradiation step of duration 32Δ. The seventh least significant bit corresponds to the irradiation step of duration 64Δ. The eighth least significant bit corresponds to the irradiation step of duration 128Δ. In other words, a single shot is divided into a number of irradiation steps equal to the number of bits n of the irradiation time control data, and each irradiation step has an irradiation time of Δ×2^{k-1}(k=1, 2, . . . , n).

The irradiation time of each irradiation step can be controlled by switching the shot enable signal. Alternatively, the irradiation time of each irradiation step may be controlled using a common blanking mechanism (not shown) that collectively controls the ON/OFF state of the beams for the entire multi-beam.

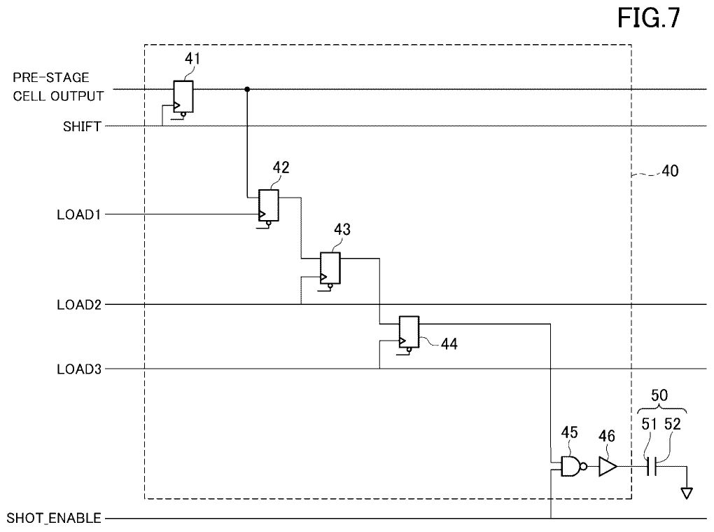

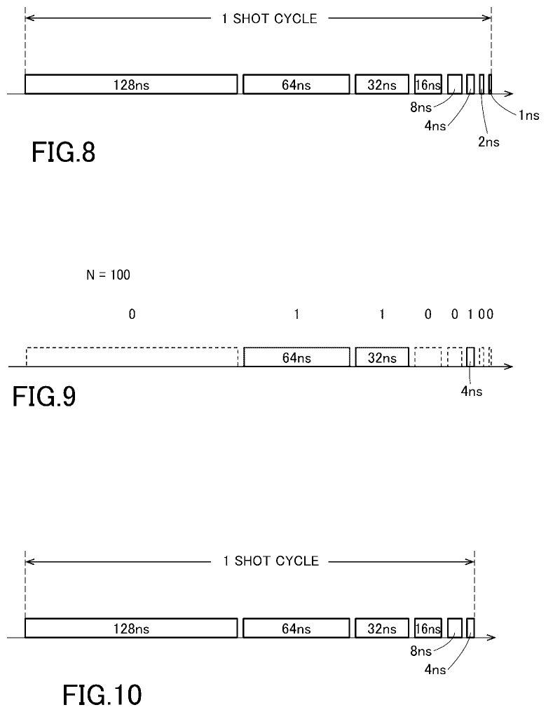

FIG. 8 illustrates an example of the irradiation steps for one shot when the number of bits n=8 and the quantization unit Δ=1 ns. In this example, the irradiation steps are carried out in order from the step with the longest irradiation time. The first irradiation step corresponds to an irradiation time of 128 ns. The second irradiation step corresponds to 64 ns. The third irradiation step corresponds to 32 ns. The fourth irradiation step corresponds to 16 ns. The fifth irradiation step corresponds to 8 ns. The sixth irradiation step corresponds to 4 ns. The seventh irradiation step corresponds to 2 ns. The eighth irradiation step corresponds to 1 ns. Note that the total irradiation time does not change even if the order of the irradiation steps is rearranged, so the steps may be performed in an order different from that shown in FIG. 8.

For N=100, the irradiation time control data is “01100100”. As shown in FIG. 9, the beam is turned on during the second (64 ns), third (32 ns), and sixth (4 ns) irradiation steps, while the beam is turned off during the first, fourth, fifth, seventh, and eighth irradiation steps.

FIG. 10 shows an example of irradiation steps for one shot, where the number of bits n=6 and the quantization unit Δ=4 ns. Compared with the example shown in FIG. 8, the larger quantization unit Δ results in a lower irradiation dose control resolution. However, because the number of irradiation steps is smaller and the data size of the irradiation time control data is reduced, the transfer time of the irradiation time control data is shorter, thereby shortening the time required for the writing process.

The patterns written on the substrate include shapes of various dimensions and forms, and the required writing accuracy differs for each shape. In this embodiment, when writing shapes that require high accuracy, the quantization unit Δ is reduced to increase the irradiation dose control resolution. Conversely, when writing shapes that require lower accuracy, the quantization unit Δ is increased to reduce the number of irradiation steps and thereby decrease the data size of the irradiation time control data.

In this way, by locally changing the irradiation dose control resolution, shapes that require high accuracy can be written with a high irradiation dose resolution, while simultaneously reducing the time required for the writing process.

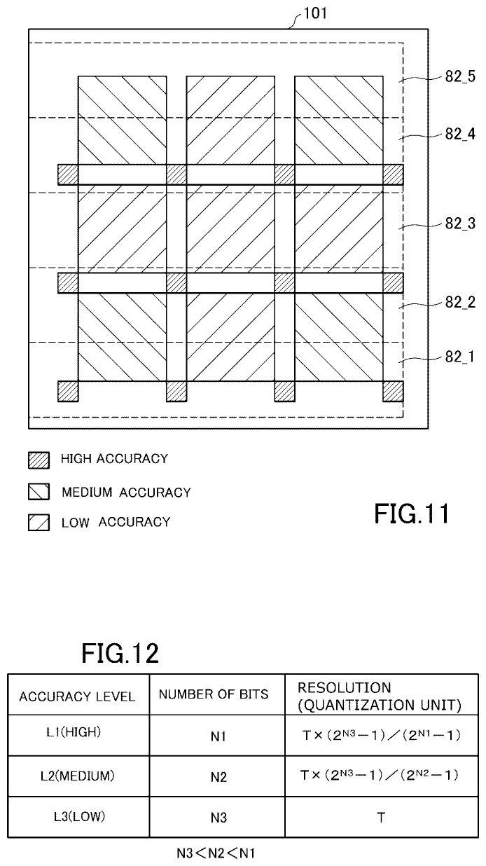

For example, when writing shapes on the substrate 101 as shown in FIG. 11, accuracy information indicating the dimensional accuracy required for each shape is assigned in advance as shape information related to writing accuracy. For instance, three levels of accuracy—high, medium, and low—may be assigned. The accuracy information is stored in the storage unit 142.

In addition, as shown in FIG. 12, a table associating dimensional accuracy, the number of bits (i.e., number of irradiation steps) of the irradiation time control data, and the irradiation dose control resolution (quantization unit Δ) is created in advance. The table is stored in the storage unit 144.

By referring to the table, the irradiation dose control resolution for writing a given stripe region 82 is determined based on the required accuracy of the patterns within that stripe region 82. For example, the irradiation dose control resolution is set according to the highest required accuracy among the patterns contained in the stripe region 82.

In the example shown in FIG. 11, stripe region 82_3 contains only patterns assigned a low accuracy. When writing stripe region 82_3, the irradiation time control data has N3 bits, and the quantization unit Δ is set to T.

Stripe region 82_5 contains patterns assigned low accuracy and patterns assigned medium accuracy. When writing stripe region 82_5, the irradiation time control data has N2 bits, and the quantization unit Δ is set to Δ=T×(2^{N3}−1)/(2^{N2}−1).

Stripe regions 82_1, 82_2, and 82_4 contain patterns assigned high accuracy. When writing stripe regions 82_1, 82_2, and 82_4, the irradiation time control data has N1 bits, and the quantization unit Δ is set to Δ=T×(2^{N3}−1)/(2^{N1}−1).

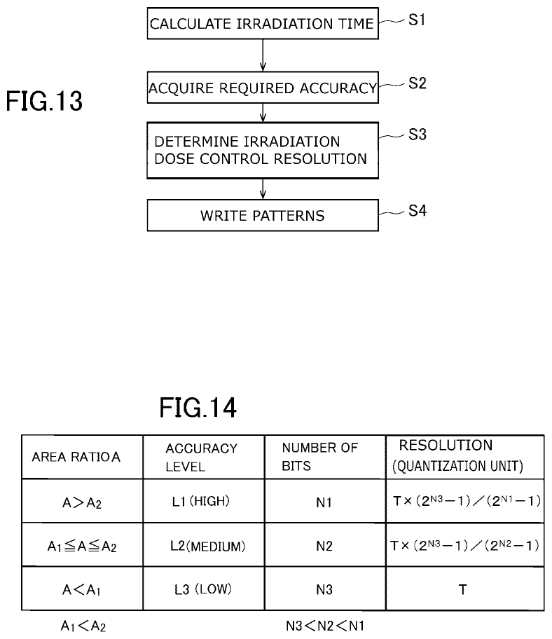

Next, the pattern writing method according to the present embodiment will be described with reference to the flowchart shown in FIG. 13. In the irradiation time calculation step (Step S1), the irradiation time calculation unit 111 calculates the irradiation dose for each shot of all beams of the multi-beam 20 that can be irradiated by the writing unit 150, and generates ON/OFF control signals.

The irradiation time calculation unit 111 first virtually divides a predetermined region (here, for example, the stripe region 82) into multiple mesh regions of a predetermined size in a mesh pattern. The size of each mesh region corresponds, for example, to the beam size of an individual beam, and each mesh region serves as a pixel of the writing target. The irradiation time calculation unit 111 reads the writing data from the storage unit 140 and calculates, for each pixel, the pattern area density ρ of the pattern located within that pixel.

The irradiation time calculation unit 111 calculates the irradiation dose D for each pixel. The irradiation dose D can be obtained, for example, by multiplying a predetermined reference irradiation dose Dbase by a proximity effect correction irradiation coefficient to correct proximity effects.

The proximity effect correction irradiation coefficient is a coefficient indicating the correction ratio determined by the backscattering rate of the proximity effect and the pattern area ratio. When the pattern area density is high, a large portion of the resist needs to be exposed by the beam, so the proximity effect correction irradiation coefficient is set to be smaller. Conversely, when the pattern area density is low, the proximity effect correction irradiation coefficient is set to be larger. By dividing the irradiation dose D by the current density, the irradiation time for each pixel can be calculated, thereby obtaining shot data (irradiation time data).

In the required accuracy acquisition step (Step S2), the writing accuracy acquisition unit 112 reads the accuracy information from the storage unit 142 and acquires the required dimensional accuracy assigned to the shapes within the stripe region 82.

In the irradiation dose control resolution determination step (Step S3), the resolution determination unit 113 refers to the table stored in the storage unit 144 and determines the irradiation dose control resolution for writing the stripe region 82 based on the required dimensional accuracy assigned to the shapes within the stripe region 82. For example, the number of bits (irradiation steps) and the irradiation dose control resolution (quantization unit Δ) of the irradiation time control data for writing the stripe region 82 are set according to the highest required accuracy among the shapes contained in the stripe region 82.

In the writing step (Step S4), the writing control unit 114 divides the irradiation time defined in the shot data by the quantization unit Δ determined in Step S3 to calculate the gradation value (quantized irradiation time), distributes the gradation value into irradiation steps, and generates the irradiation time control data.

The writing control unit 114 outputs the irradiation time control data to the deflection control circuit 130. The deflection control circuit 130 outputs the irradiation time control data to the blanking aperture array substrate 204. The input/output circuit 31 of the blanking aperture array substrate 204 transfers the irradiation time control data to the corresponding individual blanking mechanisms 40.

Within each individual blanking mechanism 40, the irradiation time control data is transferred bit by bit to the next-stage buffer according to the clock signals. Data corresponding to the irradiation time for each irradiation step is transferred, and the on/off state of the beam for each irradiation step is switched based on the irradiation time control data stored in the final buffer 44. Once one irradiation step is completed, the irradiation time control data for the next irradiation step is transferred to the buffers and the final buffer 44. In this manner, for each irradiation step, the on/off state of each beam is switched according to the irradiation time control data for that step.

The writing control unit 114 controls the writing unit 150 and executes the writing process. The writing control unit 114 uses the deflection control circuit 130 to control the deflectors 208 so that each beam of the multi-beam irradiates the corresponding pixel according to the transferred data, thereby positioning the multi-beam. After the positioning is completed, the writing control unit performs the irradiation process using the deflection control circuit 130 and carries out blanking control so that each beam of the multi-beam irradiates the corresponding pixel with the predetermined irradiation dose.

In this embodiment, stripe regions 82 that include shapes requiring high dimensional accuracy are written with a high irradiation dose control resolution, thereby achieving the desired writing accuracy. On the other hand, stripe regions 82 that include only shapes with low dimensional accuracy are written with a lower irradiation control resolution, which reduces the data transfer time for the irradiation time control data and improves throughput.

In the above embodiment, a configuration has been described in which the required dimensional accuracy is pre-assigned to the shapes to be written in order to determine the irradiation control resolution. However, the irradiation control resolution may also be determined based on the area ratio of regions with high pattern density, or based on the area ratio of shapes derived from a specific format indicating the complexity of shapes such as ellipses.

For example, the pattern density calculation unit 116 calculates the pattern density for each stripe region. The pattern density refers to the number of patterns within a unit area, for example, the number of patterns per 1 μm². The pattern density calculation unit 116 calculates the area ratio A within the stripe region that is occupied by patterns whose pattern density is equal to or greater than a predetermined threshold.

In the storage unit 144, a table, such as that shown in FIG. 14, is stored, which associates the area ratio A with the irradiation dose control resolution. The larger the area ratio A is, the higher the irradiation dose control resolution becomes. The resolution determination unit 113 refers to this table and determines the irradiation dose control resolution to be used when writing the stripe region, based on the area ratio A in the stripe region.

When determining the irradiation dose control resolution using the shape format, the shape format acquisition unit 117 acquires the shape format of the shapes within the stripe region. The shape format is defined for each shape in the writing data. The shape format acquisition unit 117 calculates the area ratio A occupied by the shapes within the stripe region, based on a predetermined format defined for the shapes.

The resolution determination unit 113 refers to a table similar to that shown in FIG. 14 and determines the irradiation dose control resolution for the stripe region based on the area ratio A within the stripe region.

In the tables shown in FIGS. 12 and 14, both the number of bits of the irradiation time control data (number of irradiation steps) and the quantization unit Δ are defined as the irradiation dose control resolution. However, it is also possible to define only one of these two parameters. When only the number of bits is defined, the maximum irradiation time calculation unit 115 calculates the maximum irradiation time among all pixels in the stripe region. The maximum irradiation time calculation unit 115 determines the quantization unit Δ so that the maximum irradiation time can be represented by the number of bits of the irradiation time control data determined by referring to the table.

When only the quantization unit Δ is defined in the table, the maximum irradiation time calculation unit 115 calculates the maximum irradiation time among all pixels in the stripe region. The maximum irradiation time calculation unit 115 divides the maximum irradiation time by the quantization unit Δ determined by referring to the table to calculate the gradation irradiation time. The quantized irradiation time is then converted into a binary number, and the number of digits, i.e., the number of bits of the irradiation time control data, is determined.

By performing the above-described steps, it is possible to determine an appropriate irradiation dose control resolution and the number of bits corresponding to the corrected irradiation dose, regardless of which irradiation modulation (correction) function is used by the user in the writing apparatus. As an example, the method for calculating the irradiation dose for each pixel was described above as multiplying the pattern area density by a proximity effect correction coefficient. However, even if other corrections such as fogging effect correction, loading effect correction, or user-applied irradiation corrections depending on mask positions or specific patterns are applied, writing can still be performed with the optimal irradiation dose control resolution while taking the corrected irradiation dose into consideration.

The number of bits n of the irradiation time control data may be determined according to the following equation based on the required dimensional accuracy and dose latitude.

2ⁿ≥A×(DL/σ_{LCD})/Pₘᵤₗₜᵢ×100

Here, σ_{LCD} the required line-width accuracy 3σ [nm], and DL is the dose latitude [nm/% dose].

In the above equation, A is a constant representing the inverse of an allowable proportion of a quantization error of a quantized (gray-scaled) irradiation dose relative to a required line-width accuracy (3σ). For example, if the allowable proportion of the quantization error within the line-width accuracy (3σ) is permitted up to 10% ( 1/10), then A=10. It is preferable that A be set, for example, in the range of 10 to 30.

In the above equation, Pₘᵤₗₜᵢ represents the number of passes when the quantized irradiation time is divided and written over multiple passes. This number of passes is not limited to stripe passes; for example, even within a single stripe pass, if the quantized irradiation time is divided and written multiple times, Pₘᵤₗₜᵢ is determined by (number of times the stripe is subdivided for writing)×(number of stripe passes). It is preferable that Pₘᵤₗₜᵢ be set, for example, in the range of 4 to 32.

The smallest natural number n that satisfies this equation is the number of bits for the irradiation time control data.

Once the number of bits of the irradiation time control data and the quantization unit Δ are determined, the length of a single shot cycle is established. The stage control unit 138 may control the stage speed such that the stage moves faster in stripe regions with shorter shot cycles than in stripe regions with longer shot cycles. This can further improve throughput.

In the above embodiment, an example in which the irradiation dose control resolution is set for each stripe region has been described; however, the irradiation dose control resolution may be set for multiple stripe regions collectively, or it may be set for each section obtained by dividing a single stripe region into multiple segments.

While certain embodiments have been described, these embodiments have been presented by way of example only and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A charged particle multi-beam writing method comprising:
calculating, from writing data, an irradiation time for each beam of each shot of a multi-beam of charged particles;
generating irradiation time control data corresponding to the calculated irradiation time for each beam at an irradiation dose control resolution determined for each region of a plurality of regions into which a writing area of a substrate is virtually divided; and
performing shots of the multi-beam based on the irradiation time control data.

2. The charged particle multi-beam writing method according to claim 1, further comprising determining, for each region, at least one of a quantization unit of the irradiation time for each beam and a number of bits representing a number of irradiation steps having different irradiation times included in each shot.

3. The charged particle multi-beam writing method according to claim 1, wherein the irradiation dose control resolution is determined based on shape information of writing patterns included in the region.

4. The charged particle multi-beam writing method according to claim 3, wherein
required accuracy is assigned to the writing patterns as the shape information, and
the irradiation dose control resolution for each region is determined based on a correspondence between the required accuracy of the writing patterns and the irradiation dose control resolution.

5. The charged particle multi-beam writing method according to claim 3, wherein
the pattern density of the writing pattern is equal to or greater than a predetermined threshold,
for each region, an area ratio of the writing patterns occupying the region is calculated, and
the irradiation dose control resolution for each region is determined based on a correspondence between the area ratio and the irradiation dose control resolution.

6. The charged particle multi-beam writing method according to claim 3, wherein,
for each region, an area ratio of the writing patterns is calculated from the shape information represented in a predetermined format, and
the irradiation dose control resolution for each region is determined based on a correspondence between the area ratio and the irradiation dose control resolution.

7. The charged particle multi-beam writing method according to claim 3, wherein
for each region, a maximum irradiation time of shots in the region is calculated, and the irradiation dose control resolution is determined using the maximum irradiation time.

8. The charged particle multi-beam writing method according to claim 2, further comprising changing a movement speed of a stage on which the substrate is placed according to a shot cycle based on the quantization unit and the number of bits.

9. The charged particle multi-beam writing method according to claim 8, wherein the writing area is virtually divided into a plurality of stripe regions with a predetermined width in a direction orthogonal to a moving direction of the stage, and the irradiation dose control resolution is determined for each stripe region.

10. A charged particle multi-beam writing apparatus comprising:
an emission unit configured to emit a multi-beam of charged particles;
a plurality of individual blanking mechanisms configured to individually perform on/off control of each beam corresponding to respective beams of the multi-beam; and
a control unit configured to calculate, from writing data, an irradiation time for each beam of each shot of the multi-beam, virtually divide a writing area of a substrate into a plurality of regions, generate irradiation time control data corresponding to the irradiation time at an irradiation dose control resolution determined for each region based on shape information of writing patterns included in the region, transfer the irradiation time control data to the individual blanking mechanisms, and control the on/off state of each beam.

11. A computer-readable storage medium storing a program that causes a computer to execute:
a process of virtually dividing a writing area of a substrate into a plurality of regions; and
a process of determining, for each of the plurality of regions, an irradiation dose control resolution for calculating, from writing data, an irradiation time for each beam of each shot of a charged particle multi-beam based on shape information of writing patterns included in the region.
